(19) United States
(12) Patent Application Publication
(10) Pub. No.: US 2009/0321780 A1
(43) Pub. Date: Dec. 31, 2009

(54) GALLIUM NITRIDE-BASED LIGHT EMITTING DEVICE WITH ROUGHENED SURFACE AND FABRICATING METHOD THEREOF

(75) Inventors: SHIH CHENG HUANG, HSINCHU CITY (TW); PO MIN TU, CHIAYI COUNTY (TW); YING CHAO YEH, TAIPEI COUNTY (TW); WEN YU LIN, TAICHUNG COUNTY (TW); PENG YI WU, TAICHUNG CITY (TW); CHIH PENG HSU, TAINAN COUNTY (TW); SHIH HSIUNG CHAN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/491,806

(22) Filed: Jun. 25, 2009

(30) Foreign Application Priority Data
Jun. 27, 2008 (TW) 097124061

(51) Int. Cl. H01L 33/00

(52) U.S. Cl. 257/101; 257/103; 438/46; 438/45; 257/E33.023

(57) ABSTRACT

A gallium nitride-based light emitting device with a roughened surface is described. The light emitting device comprises a substrate, a buffer layer grown on the substrate, an n-type III-nitride semiconductor layer grown on the buffer layer, a III-nitride semiconductor active layer grown on the n-type III-nitride semiconductor layer, a first p-type III-nitride semiconductor layer grown on the III-nitride semiconductor active layer, a heavily doped p-type III semiconductor layer grown on the first p-type III-nitride semiconductor, and a roughened second p-type III-nitride semiconductor layer grown on the heavily doped p-type III semiconductor layer.

### BACKGROUND OF THE INVENTION

1. Field of the Invention

The present invention relates to an electronic product, and relates more particularly to a light emitting device.

2. Description of the Related Art

Generally, better light emitting devices are those that emit as much light as they can generate so as to provide maximum luminance and allow users to see more clearly.

In order to increase luminance, some prior art technologies use roughened surfaces on light emitting devices. For example, U.S. Pat. No. 6,441,403 discloses a light emitting device of semiconductor, which uses a multiple quantum well structure to emit light. According to the specification of the patent, the method of fabricating the structure mainly grows an n-type (300) AlₚIn_{q}Ga_{1-p-q}N layer or a p-type (100) aluminum indium gallium nitride layer at temperatures between 400 and 1000 degrees Celsius, with four elements (Aluminum, Indium, Gallium, and Nitrogen).

The above-mentioned aluminum indium gallium nitride layer can be formed to have a rough surface with cavities thereon so as to avoid the total reflection issue that can be induced by mirror-like surfaces. However, temperatures between 400 and 1000 degrees Celsius are lower than those used in other methods, and one disadvantage of using low temperatures to grow an aluminum indium gallium nitride layer is that the epitaxial quality is not easily controlled, and quantity of defects may increase so that the resistivity of the light emitting device may increase.

Generally, electrode pads are formed on the surface of a light emitting device and metallic wires are then bonded to the electrodes, and if the aluminum indium gallium nitride layer of the light emitting device is grown at relatively low temperatures, electron holes may not easily migrate through the aluminum indium gallium nitride layer and may even be trapped such that the luminance of the light emitting device decreases.

It can be seen that even if an aluminum indium gallium nitride layer has no issues with total reflection caused by a flat surface, the luminance of a light emitting device may decrease due to low epitaxial quality. The low epitaxial quality reduces the luminance of the light emitting device before light is emitted out of the light emitting device.

U.S. Pat. No. 7,087,924 discloses a short-period super-lattice barrier buffer layer made of magnesium-nitride/indium-gallium-nitride (MgN/InₓGa₁₋ₓN). The short-period super-lattice barrier buffer layer may have a configuration of MgN up/InₓGa₁₋ₓN down or MgN down/InₓGa₁₋ₓN up, and the number of repetitions of the configuration is greater than or equal to 2 so that a surface of the device can be roughened.

The above-mentioned short-period super-lattice barrier buffer layer has a disadvantage in that the band gap thereof is small so that the layer easily absorbs the light from an active layer and the luminance of the device decreases.

Therefore, a new light emitting device that can be processed with surface roughening treatment and also maintain effective luminance is required.

### SUMMARY OF THE INVENTION

The present invention provides a gallium nitride-based light emitting device with a roughened surface, which may comprise a substrate, a buffer layer, an n-type III-nitride semiconductor layer, a III-nitride semiconductor active layer, a first p-type III-nitride semiconductor layer, a heavily doped p-type III-nitride semiconductor layer, and a roughened second p-type III-nitride semiconductor layer.

The above-mentioned buffer layer can be grown on the substrate. The n-type III-nitride semiconductor layer can be grown on the buffer layer. The III-nitride semiconductor active layer can be grown on the n-type III-nitride semiconductor layer. The first p-type III-nitride semiconductor layer can be grown on the III-nitride semiconductor active layer. The heavily doped p-type III-nitride semiconductor layer can be grown on the first p-type III-nitride semiconductor layer. The roughened second p-type III-nitride semiconductor layer can be grown on the heavily doped p-type III-nitride semiconductor layer.

The heavily doped p-type III-nitride semiconductor layer is directly formed by growing gallium nitride (GaN) at high temperatures (Tg>1000° C.) while simultaneously effecting doping of magnesium into gallium nitride.

According to the first preferred embodiment of the present invention, the doping concentration of magnesium into the heavily doped p-type III-nitride semiconductor layer is approximately 10²¹ to 10²² atoms per cubic centimeter so that a grown second p-type III-nitride semiconductor layer can have a characteristic of roughened surfaces.

The heavily doped p-type III-nitride semiconductor layer grown at high temperatures can have better epitaxial quality such that the operating characteristics of the device will not be affected.

The band gap of the heavily doped III-nitride semiconductor layer of the present invention is greater than that of a III-nitride semiconductor active layer so that there is no light absorption issue.

### BRIEF DESCRIPTION OF THE DRAWINGS

The invention will be described according to the appended drawings in which:

FIG. 1 is a sectional view showing a gallium nitride-based light emitting device with a roughened surface according to the first preferred embodiment of the present invention; and

FIG. 2 is a sectional view showing a gallium nitride-based light emitting device with a roughened surface according to the second preferred embodiment of the present invention.

### DETAILED DESCRIPTION OF THE INVENTION

One aspect of the present invention proposes a light emitting device. In order to provide a thorough understanding of the present invention, a detailed description of a number of method steps and components is provided below. Clearly, the practice of the present invention is not limited to any specific detail of a light emitting device that is familiar to one skilled in the art. On the other hand, components or method steps which are well-known are not described in detail to avoid unnecessary limitations. A preferred embodiment of the present invention will be described in detail. However, in addition to the preferred embodiment described, other embodiments can be broadly employed, and the scope of the present invention is not limited by any of the embodiments, but should be defined in accordance with the following claims and their equivalent.

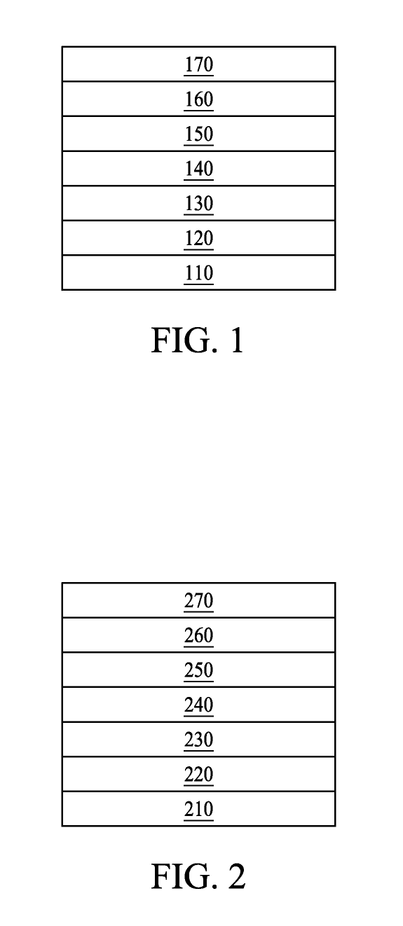

FIG. 1 is a sectional view showing a gallium nitride-based light emitting device with a roughened surface according to the first preferred embodiment of the present invention. Referring to FIG. 1, the above gallium nitride-based light emitting device with a roughened surface may comprise a substrate 110, a buffer layer 120, an n-type III-nitride semiconductor layer 130, a III-nitride semiconductor active layer 140, a first p-type III-nitride semiconductor layer 150, a heavily doped p-type III-nitride semiconductor layer 160, and a roughened second p-type III-nitride semiconductor layer 170.

The above-described n type and p type are different conductive types, wherein the n type is the first conductive type and the p type is the second conductive type.

The above-mentioned buffer layer 120 can be grown on the substrate 110. The n-type III-nitride semiconductor layer 130 can be grown on the buffer layer 120. The III-nitride semiconductor active layer 140 can be grown on the n-type III-nitride semiconductor layer 130. The first p-type III-nitride semiconductor layer 150 can be grown on the III-nitride semiconductor active layer 140. The heavily doped p-type III-nitride semiconductor layer 160 can be grown on the first p-type III-nitride semiconductor layer 150. The roughened second p-type III-nitride semiconductor layer 170 can be grown on the heavily doped p-type III-nitride semiconductor layer 160.

The buffer layer 120 can be an indium gallium nitride (InₓGa_{1 -x}N/In_{y}Ga_{1-y}N) super-lattice buffer layer.

The material of the heavily doped p-type III-nitride semiconductor layer 160 is neither magnesium nitride (MgN) nor indium gallium nitride (InₓGa₁₋ₓN). The heavily doped p-type III-nitride semiconductor layer 160 is directly formed by growing gallium nitride (GaN) at high temperatures (Tg>1000° C.) while simultaneously effecting doping of magnesium into gallium nitride. As such, the grown layer is a type of p-type gallium nitride (GaN) epitaxial layer. The epitaxial layer grown at high temperatures can have better epitaxial quality such that the operating characteristics of the device will not be affected.

Generally, the doping concentration of magnesium is about 10²⁰ atoms per cubic centimeter. However, the above-mentioned doping of magnesium is performed in a heavy doping condition. According to the first preferred embodiment of the present invention, the doping concentration of magnesium into the heavily doped p-type III-nitride semiconductor layer 160 is approximately 10²¹ to 10²² atoms per cubic centimeter so that a grown second p-type III-nitride semiconductor layer 170 can have a characteristic of roughened surfaces.

It should be noted that the magnesium dopant in the p-type gallium nitride (GaN) epitaxial layer is heavily doped into the p-type gallium nitride epitaxial layer. The above-mentioned heavily doped p-type III-nitride semiconductor layer 160 is not a magnesium nitride layer. A magnesium nitride layer does not include the element gallium (Ga) like the heavily doped p-type III-nitride semiconductor layer 160 does.

Generally, the resistivity of a magnesium nitride layer is high. Electrons migrating through the magnesium nitride (MgN) layer with high resistivity require high driving power. The heavily doped p-type III-nitride semiconductor layer 160 of the present invention does not include a magnesium nitride (MgN) layer so that high driving power is not needed.

The ratio of magnesium to nitrogen in the heavily doped p-type III-nitride semiconductor layer 160 of the present invention is less than 0.01 such that the heavily doped p-type III-nitride semiconductor layer 160 does not become an alloy layer. As to a prior art magnesium nitride (MgN) layer, in which the ratio of magnesium to nitrogen is about 1, and the MgN layer is an alloy layer. Consequently, the magnesium-nitrogen composition in the heavily doped p-type III-nitride semiconductor layer 160 is different from the magnesium-nitrogen compound in an MgN layer.

Moreover, the heavily doped p-type III-nitride semiconductor layer 160 of the present invention does not include the element Indium (In). In prior art light emitting layers of indium gallium nitride (InₓGa₁₋ₓN), if the concentration ratio of indium is too high, the InₓGa₁₋ₓN layers may have light absorbing characteristic, and therefore the luminance of the light emitting layers decreases. The heavily doped p-type III-nitride semiconductor layer 160 of the present invention does not include the element Indium (In) so as to ensure the luminance of a device using the layer 160.

Furthermore, the band gap of the heavily doped III-nitride semiconductor layer is greater than that of a III-nitride semiconductor active layer, so there is no light absorption issue.

FIG. 2 is a sectional view showing a gallium nitride-based light emitting device with a roughened surface according to the second preferred embodiment of the present invention. Referring to FIG. 2, the above gallium nitride-based light emitting device with a roughened surface may comprise a substrate 210, a buffer layer 220, a p-type III-nitride semiconductor layer 230, a III-nitride semiconductor active layer 240, a first n-type III-nitride semiconductor layer 250, an heavily doped n-type III-nitride semiconductor layer 260, and a roughened second n-type III-nitride semiconductor layer 270.

The above described n type and p type are different conductive types, wherein the p type is the first conductive type and the n type is the second conductive type.

The buffer layer 220 can be grown on the substrate 210. The p-type III-nitride semiconductor layer 230 can be grown on the buffer layer 220. The III-nitride semiconductor active layer 240 can be grown on the p-type III-nitride semiconductor layer 230. The first n-type III-nitride semiconductor layer 250 can be grown on the III-nitride semiconductor active layer 240. The heavily doped n-type III-nitride semiconductor layer 260 can be grown on the first n-type III-nitride semiconductor layer 250. The roughened second n-type III-nitride semiconductor layer 270 can be grown on the heavily doped n-type III-nitride semiconductor layer 260.

The buffer layer 220 can be an indium gallium nitride (InₓGa_{1- -x}N/In_{y}Ga_{1-y}N) super-lattice buffer layer.

The material of the above-mentioned heavily doped n-type III-nitride semiconductor layer 260 is neither silicon nitride (SiN) nor indium gallium nitride (InₓGa₁₋ₓN). The heavily doped n-type III-nitride semiconductor layer 260 is directly formed by growing gallium nitride (GaN) at high temperatures (Tg>1000° C.) while simultaneously effecting doping of silicon (Si) into gallium nitride. As such, the grown layer is a type of n-type gallium nitride (GaN) epitaxial layer. The epitaxial layer grown at high temperatures can have better epitaxial quality such that the operating characteristics of the device will not be affected.

Generally, the doping concentration of silicon is about 10¹⁸ atoms per cubic centimeter. However, the above-mentioned doping of silicon (Si) is performed in a heavy doping condition. According to the second preferred embodiment of the present invention, the doping concentration of silicon into the heavily doped n-type III-nitride semiconductor layer 260 is approximately 10¹⁹ to 10²¹ atoms per cubic centimeter so that a grown second n-type III-nitride semiconductor layer 270 can have a characteristic of roughened surfaces.

It should be noted that the silicon dopant in the n-type gallium nitride (GaN) epitaxial layer is heavily doped into the n-type gallium nitride epitaxial layer. The heavily doped n-type III-nitride semiconductor layer 260 is not a silicon nitride (SiN) layer. A SiN layer does not include the element Ga like the heavily doped n-type III-nitride semiconductor layer 260 does.

Generally, the resistivity of a SiN layer is high. Electrons migrating through the SiN layer with high resistivity require high driving power. The heavily doped n-type III-nitride semiconductor layer 260 of the present invention does not include a SiN layer so that high driving power is not required.

The ratio of silicon to nitrogen in the heavily doped n-type III-nitride semiconductor layer 260 of the present invention is less than 0.01 such that the heavily doped n-type III-nitride semiconductor layer 260 is not a silicon nitride layer. As to a prior art silicon nitride (SiN) layer, in which the ratio of silicon to nitrogen is about 1, the SiN layer is a compound layer. Consequently, the silicon-nitrogen composition in the heavily doped p-type III-nitride semiconductor layer 260 of the present invention is different from the silicon nitride compound in a SiN layer.

Moreover, the heavily doped n-type III-nitride semiconductor layer 260 of the present invention does not include the element Indium (In). In prior art light emitting layers of indium gallium nitride (InₓGa₁₋ₓN), if the concentration ratio of indium is too high, the InₓGa₁₋ₓN layers may have light absorbing characteristic, and therefore the luminance of the light emitting layers decreases. The heavily doped n-type III-nitride semiconductor layer 260 of the present invention does not include the element Indium (In) so as to ensure the luminance of a device using the layer 260.

Furthermore, the band gap of the heavily doped III-nitride semiconductor layer is greater than that of a III-nitride semiconductor active layer so that there is no light absorption issue.

The third preferred embodiment of the present invention proposes a method of fabricating a gallium nitride-based light emitting device with a roughened surface. Referring to FIG. 1, the method initially forms a buffer layer 120 on a substrate 110. Next, an n-type III-nitride semiconductor layer 130 is formed on the buffer layer 120. Then, a III-nitride semiconductor active layer 140 is formed on the n-type III-nitride semiconductor layer 130. Thereafter, a first p-type III-nitride semiconductor layer 150 is formed on III-nitride semiconductor active layer 140. Next, a heavily doped p-type III semiconductor layer 160 is formed on the first p-type III-nitride semiconductor layer 150. Finally, a roughened second p-type III-nitride semiconductor layer 170 is formed on the heavily doped p-type III-nitride semiconductor layer 160.

The above described n type and p type are different conductive types, wherein the n type is the first conductive type and the p type is the second conductive type.

The above-mentioned buffer layer 120 can be an indium gallium nitride (InₓGa₁₋ₓN/In_{y}Ga_{1-y}N) super-lattice buffer layer.

The material of the above-mentioned heavily doped p-type III-nitride semiconductor layer 160 is neither magnesium nitride (MgN) nor indium gallium nitride (InₓGa₁₋ₓN). The heavily doped p-type III-nitride semiconductor layer 160 is directly formed by growing gallium nitride (GaN) at high temperatures (Tg>1000° C.) while simultaneously effecting doping of Magnesium into gallium nitride. As such, the grown layer is a type of p-type gallium nitride (GaN) epitaxial layer. The epitaxial layer grown at high temperatures can have better epitaxial quality such that the operating characteristics of the device will not be affected.

Generally, the doping concentration of magnesium is about 10²⁰ atoms per cubic centimeter. However, the above-mentioned doping of magnesium is performed in a heavy doping condition. According to the third preferred embodiment of the present invention, the doping concentration of magnesium into the heavily doped p-type III-nitride semiconductor layer 160 is approximately 10²¹ to 10²² atoms per cubic centimeter so that a grown second p-type III-nitride semiconductor layer 170 can have a characteristic of roughened surfaces.

It should be noted that the magnesium dopant in the p-type gallium nitride (GaN) epitaxial layer is heavily doped into the p-type gallium nitride epitaxial layer. The heavily doped p-type III-nitride semiconductor layer 160 is not a magnesium nitride layer. A magnesium nitride layer does not include the element Ga like the heavily doped p-type III-nitride semiconductor layer 160 does.

Generally, the resistivity of a magnesium nitride layer is high. Electrons migrating through the magnesium nitride (MgN) layer with high resistivity require high driving power. The heavily doped p-type III-nitride semiconductor layer 160 of the present invention does not include a magnesium nitride (MgN) layer so that high driving power is not required.

The ratio of magnesium to nitrogen in the heavily doped p-type III-nitride semiconductor layer 160 of the present invention is less than 0.01 such that the heavily doped p-type III-nitride semiconductor layer 160 does not become an alloy layer. As to a prior art magnesium nitride (MgN) layer, in which the ratio of magnesium to nitrogen is about 1, the MgN layer is an alloy layer. Consequently, the magnesium-nitrogen composition in the heavily doped p-type III-nitride semiconductor layer 160 is different from the magnesium-nitrogen compound in an MgN layer.

Moreover, the heavily doped p-type III-nitride semiconductor layer 160 of the present invention does not include the element Indium (In). In prior art light emitting layers of indium gallium nitride (InₓGa₁₋ₓN), if the concentration ratio of indium is too high, the InₓGa₁₋ₓN layers may have light absorbing characteristic, and therefore the luminance of the light emitting layers decreases. The heavily doped p-type III-nitride semiconductor layer 160 of the present invention does not include the element Indium (In) so as to ensure the luminance of a device using the layer 160.

Furthermore, the band gap of the heavily doped III-nitride semiconductor layer is greater than that of a III-nitride semiconductor active layer so that there is no light absorption issue.

The fourth preferred embodiment of the present invention proposes a method of fabricating a gallium nitride-based light emitting device with a roughened surface. Referring to FIG. 2, the method initially forms a buffer layer 220 on a substrate 210. Next, a p-type III-nitride semiconductor layer 230 is formed on the buffer layer 220. Then, a III-nitride semiconductor active layer 240 is formed on the p-type III-nitride semiconductor layer 230. Thereafter, a first n-type III-nitride semiconductor layer 250 is formed on III-nitride semiconductor active layer 240. Next, an heavily doped n-type III-nitride semiconductor layer 260 is formed on the first n-type III-nitride semiconductor layer 250. Finally, a roughened second n-type III-nitride semiconductor layer 270 is formed on the heavily doped n-type III-nitride semiconductor layer 260.

The above described n type and p type are different conductive types, wherein the p type is the first conductive type and the n type is the second conductive type.

The above-mentioned buffer layer 220 can be an indium gallium nitride (InₓGa₁₋ₓN/In_{y}Ga_{1-y}N) super-lattice buffer layer.

The material of the above-mentioned heavily doped n-type III-nitride semiconductor layer 260 is neither silicon nitride (SiN) nor indium gallium nitride (InₓGa₁₋ₓN). The above-mentioned heavily doped n-type III semiconductor layer 260 is directly formed by growing gallium nitride (GaN) at high temperatures (Tg>1000° C.) while simultaneously effecting doping of silicon (Si) into gallium nitride. As such, the grown layer is a type of n-type gallium nitride (GaN) epitaxial layer. The epitaxial layer grown at high temperatures can have better epitaxial quality such that the operating characteristics of the device will not be affected.

Generally, the doping concentration of silicon is about 10¹⁸ atoms per cubic centimeter. However, the above-mentioned doping of silicon (Si) is performed in a heavy doping condition. According to the fourth preferred embodiment of the present invention, the doping concentration of silicon into the heavily doped n-type III-nitride semiconductor layer 260 is approximately 10¹⁹ to 10²¹ atoms per cubic centimeter so that a grown second n-type III-nitride semiconductor layer 270 can have a characteristic of roughened surfaces.

It should be noted that the silicon dopant in the n-type gallium nitride (GaN) epitaxial layer is heavily doped into the n-type gallium nitride epitaxial layer. The heavily doped n-type III-nitride semiconductor layer 260 is not a silicon nitride (SiN) layer. A SiN layer does not include the element Ga like the heavily doped p-type III-nitride semiconductor layer 260 does.

Generally, the resistivity of a SiN layer is high. Electrons migrating through the SiN layer with high resistivity require high driving power. The heavily doped n-type III-nitride semiconductor layer 260 of the present invention does not include a SiN layer so that high driving power is not required.

The ratio of silicon to nitrogen in the heavily doped n-type III-nitride semiconductor layer 260 of the present invention is less than 0.01 such that the heavily doped n-type III-nitride semiconductor layer 260 is not a silicon nitride layer. As to a prior art silicon nitride (SiN) layer, in which the ratio of silicon to nitrogen is about 1, the SiN layer is a compound layer. Consequently, the silicon-nitrogen composition in the heavily doped p-type III-nitride semiconductor layer 260 is different from the silicon nitride compound in a SiN layer.

Moreover, the heavily doped n-type III-nitride semiconductor layer 260 of the present invention does not include the element Indium (In). In prior art light emitting layers of indium gallium nitride (InₓGa₁₋ₓN), if the concentration ratio of indium is too high, the InₓGa₁₋ₓN layers may have light absorbing characteristic, and therefore the luminance of the light emitting layers decreases. The heavily doped n-type III-nitride semiconductor layer 260 of the present invention does not include the element Indium (In) so as to ensure the luminance of a device using the layer 260.

The invention proposes a method for separating a semiconductor from a substrate, which can lower production costs, does not require a transparent substrate, and moreover does not affect the material of each layer.

The above-described embodiments of the present invention are intended to be illustrative only. Numerous alternative embodiments may be devised by persons skilled in the art without departing from the scope of the following claims.

What is claimed is:

1. A gallium nitride-based light emitting device with a roughened surface, comprising:
a substrate;
a buffer layer formed on said substrate;
a III-nitride semiconductor layer of a first conductive type formed on said buffer layer;
a III-nitride semiconductor active layer formed on said III-nitride semiconductor layer of said first conductive type
a first III-nitride semiconductor layer of a second conductive type formed on said III-nitride semiconductor active layer, wherein said first conductive type and said second conductive type are opposite;
a heavily doped III-nitride semiconductor layer of said second conductive type formed on said first III-nitride semiconductor layer of said second conductive type; and
a roughened second III-nitride semiconductor layer of said second conductive type formed on said heavily doped III-nitride semiconductor layer of said second conductive type.

2. The gallium nitride-based light emitting device with a roughened surface according to claim 1, wherein said first conductive type is n-type and said second conductive type is p-type.

3. The gallium nitride-based light emitting device with a roughened surface according to claim 1, wherein said first conductive type is p-type and said second conductive type is n-type.

4. The gallium nitride-based light emitting device with a roughened surface according to claim 2, wherein a concentration of said heavily doped p-type III-nitride semiconductor layer is between about 10²¹-10²²/cm³.

5. The gallium nitride-based light emitting device with a roughened surface according to claim 2, wherein the dopant of said p-type is Mg.

6. The gallium nitride-based light emitting device with a roughened surface according to claim 2, wherein a concentration of said heavily doped n-type III-nitride semiconductor layer is between about 10¹⁹-10²¹/cm³.

7. The gallium nitride-based light emitting device with a roughened surface according to claim 2, wherein the dopant of said n-type is Si.

8. The gallium nitride-based light emitting device with a roughened surface according to claim 1, wherein the material of said heavily doped III-nitride semiconductor layer of said second conductive type is gallium nitride.

9. A method for fabricating a gallium nitride-based light emitting device with a roughened surface, comprising steps of:
forming a buffer layer on a substrate;
forming a III-nitride semiconductor layer of a first conductive type on said buffer layer;
forming a III-nitride semiconductor active layer on said III-nitride semiconductor layer of said first conductive type;
forming a first III-nitride semiconductor layer of a second conductive type formed on said III-nitride semiconductor active layer;
forming a first III-nitride semiconductor layer of a second conductive type on said III-nitride semiconductor active layer;
forming a heavily doped III-nitride semiconductor layer of said second conductive type on said first III nitride semiconductor layer of said second conductive type, wherein said first conductive type and said second conductive type are opposite; and
forming a roughened second III-nitride semiconductor layer of said second conductive type on said heavily doped III-nitride semiconductor layer of said second conductive type.

10. The method for fabricating a gallium nitride-based light emitting device with a roughened surface according to claim 9, wherein the temperature for forming said heavily doped III-nitride semiconductor layer of said second conductive type is greater than 1000° C.

11. The method for fabricating a gallium nitride-based light emitting device with a roughened surface according to claim 9, wherein said first conductive type is n-type and said second conductive type is p-type.

12. The method for fabricating a gallium nitride-based light emitting device with a roughened surface according to claim 9, wherein said first conductive type is p-type and said second conductive type is n-type.

13. The method for fabricating a gallium nitride-based light emitting device with a roughened surface according to claim 11, wherein a concentration of said heavily doped p-type III-nitride semiconductor layer is between about 10²¹-10²²/cm³.

14. The method for fabricating a gallium nitride-based light emitting device with a roughened surface according to claim 11, wherein the dopant of said p-type is Mg.

15. The method for fabricating a gallium nitride-based light emitting device with a roughened surface according to claim 11, wherein a concentration of said heavily doped n-type III-nitride semiconductor layer is between about 10¹⁹-10²¹/cm³.

16. The method for fabricating a gallium nitride-based light emitting device with a roughened surface according to claim 11, wherein the dopant of said n-type is Si.

17. The method for fabricating a gallium nitride-based light emitting device with a roughened surface according to claim 9, wherein the material of said heavily doped III-nitride semiconductor layer of said second conductive type is gallium nitride.
